(19) United States
(12) Patent Application Publication
(10) Pub. No.: US 2014/0008670 A1
(43) Pub. Date: Jan. 9, 2014

(54) THIN FILM TRANSISTOR ARRAY SUBSTRATE AND LIQUID CRYSTAL DISPLAY USING THE SAME

(71) Applicant: Mitsubishi Electric Corporation, Tokyo (JP)

(72) Inventor: Kazunori OKUMOTO, Tokyo (JP)

(21) Appl. No.: 13/928,090

(22) Filed: Jun. 26, 2013

(30) Foreign Application Priority Data
Jul. 4, 2012 (JP) 2012-150309

(51) Int. Cl. H01L 33/00

(52) U.S. Cl. CPC H01L 33/0041
USPC 257/88

(57) ABSTRACT

A TFT array substrate includes a gate wiring for driving a pixel electrode constituting a pixel on an insulating substrate, a source wiring intersecting with the gate wiring through an insulating film, a source electrode connected to the source wiring, and a drain electrode provided opposite to the source electrode and connected to the pixel electrode. A semiconductor layer to be connected to the source electrode and the drain electrode is provided under the source electrode and the drain electrode. An end face of the semiconductor layer does not intersect with an end face of the source wiring, an end face of the source electrode and an end face of the drain electrode over the gate wiring, and a portion of the semiconductor layer which is positioned under the drain electrode has an end face to be included in the gate wiring as seen in a planar view.

### BACKGROUND OF THE INVENTION

1. Field of the Invention

The present invention relates to a thin film transistor and a liquid crystal display using the same.

2. Description of the Background Art

A liquid crystal display usually has a structure in which a liquid crystal to be a display material is interposed between two insulating substrates opposed to each other and is constituted to enable selective application of a voltage to the liquid crystal every pixel. For at least one of the two insulating substrates, there is used a substrate (hereinafter referred to as a “TFT array substrate”) on which a switching element such as a thin film transistor (TFT) to be provided in each pixel and a pixel electrode to be connected thereto are formed. A plurality of gate wirings and a plurality of source wirings are provided on the TFT array substrate so as to intersect with each other. The gate wirings serve to control the switching element of each pixel, thereby driving the pixel electrode. The source wirings serve to supply a pixel signal to the pixel electrode via each switching element. Each pixel is formed in each region surrounded by the gate wiring and the source wiring and is provided in a matrix.

The liquid crystal display according to the related art has a problem in that deterioration in display characteristics, for example, a crosstalk, luminance unevenness, reduction in contrast and the like, occurrence of a point defect (a poor pixel), or the like is caused by the outflow of an electric charge of the pixel electrode to the source wiring due to a leakage current of the TFT of each pixel.

Japanese Patent Application Laid-Open No. 2003-303973 discloses the following two types of a leakage current generated in a TFT of a liquid crystal display. One of them is a leakage current (a light leakage current) through a carrier generated by irradiating light (backlight light) obtained by a backlight on a semiconductor layer provided under a drain electrode of the TFT. The other is a leakage current setting, as a leakage path, each of end faces of a semiconductor layer, a source electrode and a drain electrode which constitute a TFT.

Japanese Patent Application Laid-Open No. 2003-303973 proposes the technique for causing a portion provided under the drain electrode in the semiconductor layer of the TFT to be included in a gate electrode as seen in a planar view and preventing the end face of the semiconductor layer from intersecting with the end face of the source electrode over the gate electrode (the end face of the semiconductor layer and the end face of the source wiring are caused to intersect with each other at an outside of the gate electrode) as a countermeasure to be taken against the leakage currents. The semiconductor layer provided under the drain electrode of the TFT is included in the gate electrode as seen in a planar view so that the backlight light is blocked by the gate electrode and is not irradiated on the semiconductor layer. Consequently, it is possible to suppress the generation of a carrier which might cause a light leakage current. Moreover, an electric conductivity of the leakage path on the end face of the semiconductor layer fluctuates by the influence of an electric field generated from the gate electrode. For this reason, an intersection point of the end face of the source wiring and the end face of the semiconductor layer is positioned on the outside of the gate electrode so that a resistance in that portion is raised and a leakage current flowing into the source wiring is thus reduced.

In a TFT array substrate described in Japanese Patent Application Laid-Open No. 2003-303973, the end face of the source electrode and the end face of the semiconductor layer do not intersect with each other over the gate electrode. However, the end face of the drain electrode intersects with the end face of the semiconductor layer over the gate wiring, and any leakage current flows through the intersection point.

In the case in which a gate voltage has a deep bias, particularly, the electric conductivity of the semiconductor layer is reduced so that the leakage path functions or a new leakage path from the end face of the semiconductor layer into the face is formed. Consequently, a leakage current through an intersection point is increased to cause a point defect. Under a driving condition for causing the gate voltage to have a deep bias, for example, in the case in which line common inversion driving or the like is carried out, accordingly, there is caused a problem in that a yield is reduced by the point defect.

Moreover, the characteristic of the TFT is closely related to a manufacturing process condition or a material. For this reason, there is also a problem in that the manufacturing process condition or selection of the material is limited in the case in which a leakage current is generated in the TFT.

### SUMMARY OF THE INVENTION

It is an object of the present invention to provide a TFT array substrate capable of suppressing a leakage current of a TFT of each pixel also under the condition that a gate voltage has a deep bias, and a liquid crystal display.

A thin film transistor array substrate according to the present invention includes a gate wiring for driving a pixel electrode constituting a pixel on an insulating substrate, a source wiring intersecting with the gate wiring through an insulating film, a source electrode connected to the source wiring, a drain electrode provided opposite to the source electrode and connected to the pixel electrode, and a semiconductor layer connected to the source electrode and the drain electrode and provided under the source electrode and the drain electrode. An end face of the semiconductor layer does not intersect with an end face of the source wiring, an end face of the source electrode and an end face of the drain electrode over the gate wiring. A portion of the semiconductor layer which is positioned under the drain electrode has an end face to be included in the gate wiring as seen in a planar view.

Neither an intersection point of the end face of the source electrode and the end face of the semiconductor layer nor an intersection point of the end face of the drain electrode and the end face of the semiconductor layer are present over the gate wiring. Even if a gate voltage has a deep bias, accordingly, the end face of the semiconductor layer can be prevented from serving as a leakage path so that a leakage current of the TFT can be suppressed. Consequently, it is possible to suppress the occurrence of a point defect of a display device, thereby contributing to enhancement in a yield.

Moreover, at least a part of the semiconductor layer is included in the gate wiring as seen in a planar view under the drain electrode. Consequently, there is reduced an area on which backlight light is irradiated in the semiconductor layer provided under the drain electrode. Therefore, a light leakage current of the TFT is suppressed. Thus, it is possible to suppress deterioration in display characteristics, for example, luminance unevenness, reduction in contrast and the like in the liquid crystal display.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing a structure of a TFT provided in a TFT array substrate according to a first preferred embodiment;

FIG. 2 is a sectional view showing the structure of the TFT provided in the TFT array substrate according to the first preferred embodiment;

FIG. 3 is a sectional view showing the structure of the TFT provided in the TFT array substrate according to the first preferred embodiment;

FIG. 4 is a plan view showing a structure of a TFT provided in a TFT array substrate according to a second preferred embodiment; and

FIG. 5 is a plan view showing a structure of a TFT provided in a TFT array substrate according to a third preferred embodiment.

### DESCRIPTION OF THE PREFERRED EMBODIMENTS

### First Preferred Embodiment

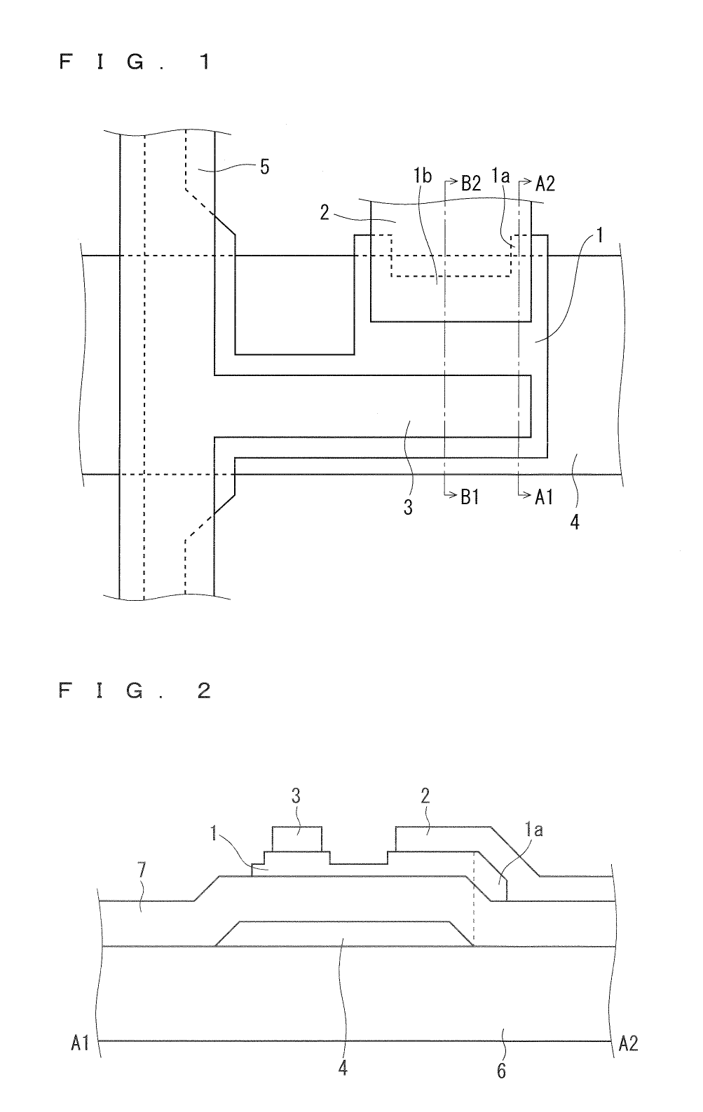

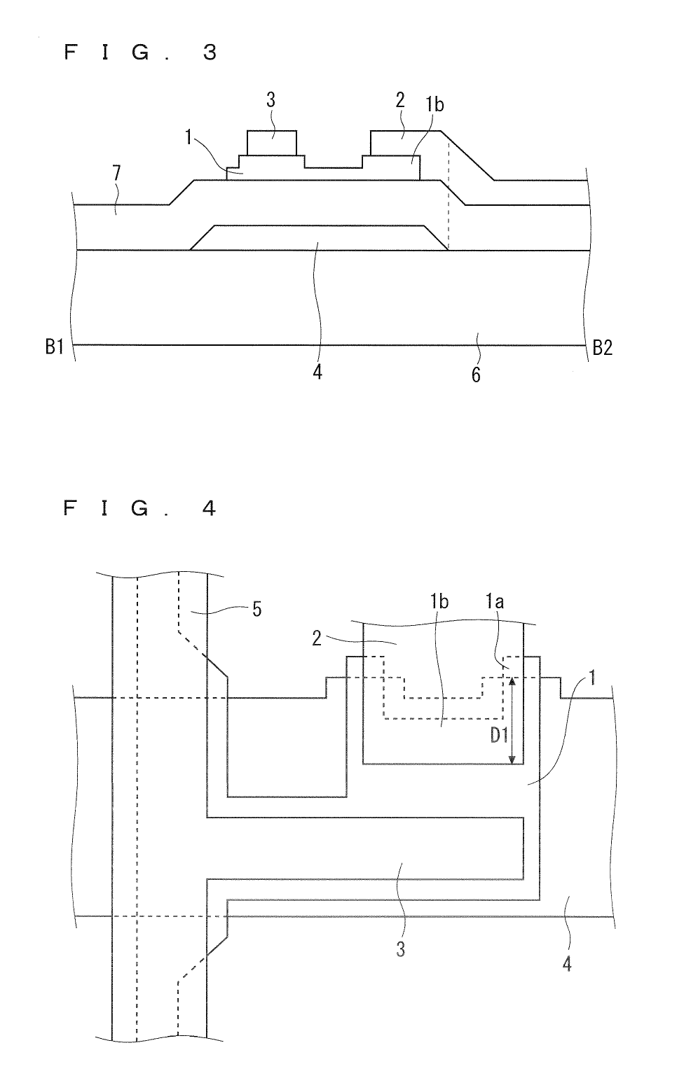

FIGS. 1 to 3 are views showing a structure of a TFT provided in a TFT array substrate according to a first preferred embodiment of the present invention. FIG. 1 is a plan view showing the TFT, and FIGS. 2 and 3 are sectional views taken along A1-A2 line and B1-B2 line illustrated in FIG. 1, respectively.

The TFT array substrate includes a gate wiring 4 and a source wiring 5 which are formed on an insulating substrate 6 and intersect with each other through an insulating film 7 (the insulating substrate 6 and the insulating film 7 are not shown in FIG. 1). A part of the gate wiring 4 functions as a gate electrode of the TFT and serves to send a control signal to the TFT, thereby driving a pixel electrode constituting a pixel. The source wiring 5 is formed on an upper layer of the gate wiring 4 through the insulating film 7 and serves to supply an image signal to the pixel electrode via the TFT. The gate wirings 4 and the source wirings 5 are provided on the insulating substrate 6 respectively and the pixel electrode constituting the pixel is formed in each of regions surrounded by the gate wirings 4 and the source wirings 5, which is not shown.

The TFT includes a source electrode 3 provided in the vicinity of an intersection point of the gate wiring 4 and the source wiring 5 and connected to the source wiring 5, a drain electrode 2 provided opposite to the source electrode 3, and a semiconductor layer 1 provided under the source electrode 3 and the drain electrode 2.

The semiconductor layer 1 is connected to the source electrode 3 and the drain electrode 2 above the gate wiring 4 through the insulating film 7. A portion of the semiconductor layer 1 which is positioned on the gate wiring 4 functions as a channel region in which a channel for conducting the drain electrode 2 and the source electrode 3 is formed when a predetermined voltage is applied to the gate wiring 4 so that the TFT is turned ON. In other words, a portion of the gate wiring 4 which is positioned under the semiconductor layer 1 between the drain electrode 2 and the source electrode 3 functions as the gate electrode of the TFT.

The drain electrode 2 and the source electrode 3 are formed by using the same layer as the source wiring 5, and the source electrode 3 is connected to the source wiring 5 above the gate wiring 4. In other words, the source electrode 3 is a portion which branches from the source wiring 5 above the gate wiring 4. A part of the drain electrode 2 is extended to an outside of the gate wiring 4 and is thus connected to the pixel electrode (not shown).

The semiconductor layer 1 is also provided on a lower layer of the source wiring 5. The semiconductor layer 1 branches from the lower layer of the source wiring 5 along the source electrode 3 and is thus extended to a portion provided under the drain electrode 2, and a region between the drain electrode 2 and the source electrode 3 in the branching portion constitutes the channel region of the TFT. In other words, a portion provided under the source wiring 5 and a portion constituting the TFT in the semiconductor layer 1 are connected to each other above the gate wiring 4.

As shown in FIG. 1, the semiconductor layer 1 includes all end faces of the source electrode 3 and the drain electrode 2 as seen in a planar view and an end face of the source wiring 5 on a side where the source electrode 3 is connected over the gate wiring 4. An end face of the source wiring 5 at a reverse side to the source electrode 3 is not included in the semiconductor layer 1 but is provided in parallel with an end face of the semiconductor layer 1. Accordingly, the end face of the semiconductor layer 1 does not intersect with the end face of the source wiring 5, the end face of the source electrode 3 and the end face of the drain electrode 2 over the gate wiring 4.

A part of the semiconductor layer 1 is protruded outward from the gate wiring 4 in the vicinity of the drain electrode 2 in such a manner that the end face of the semiconductor layer 1 and the end face of the drain electrode 2 intersect with each other at the outside of the gate wiring 4. However, most parts of the end face of the semiconductor layer 1 are included in the gate wiring 4 under the drain electrode 2, and an area of a portion of the semiconductor layer 1 which is protruded from the gate wiring 4 is reduced. Accordingly, the semiconductor layer 1 positioned under the drain electrode 2 has a structure including a protruded portion 1a (a first portion) which is protruded outward from the gate wiring 4 as seen in a planar view and has an end face intersecting with the end face of the drain electrode 2, and a retracted portion 1b (a second portion) which has an end face retracted from the end face of the gate wiring 4 as seen in a planar view.

Moreover, the end face of the semiconductor layer 1 and the end face of the source wiring 5 are also constituted to intersect with each other at the outside of the gate wiring 4 as shown in FIG. 1.

Thus, the TFT provided in the TFT array substrate according to the present preferred embodiment has a structure in which the end face of the semiconductor layer 1 does not intersect with the end face of the drain electrode 2 as well as the end face of the source wiring 5 and the end face of the source electrode 3 over the gate wiring 4. Accordingly, a leakage path for the end face of the semiconductor layer 1 is not generated under a deep bias of a gate voltage. Therefore, it is possible to prevent a point defect of the liquid crystal display from being caused by the leakage current of the TFT of each pixel. Consequently, it is possible to contribute to enhancement in a yield.

Furthermore, the semiconductor layer 1 positioned under the drain electrode 2 has most parts included in the gate wiring 4. For this reason, backlight light is blocked by the gate wiring 4 and does not reach the semiconductor layer 1 in that portion. In other words, a portion of the semiconductor layer 1 provided under the drain electrode 2 on which the backlight light is directly irradiated is only the protruded portion 1a provided in the vicinity of the end of the drain electrode 2, and the number of carriers to be generated in the semiconductor layer 1 provided under the drain electrode 2 is thus reduced. Therefore, the light leakage current of the TFT is suppressed. Consequently, it is possible to suppress deterioration in display characteristics, for example, luminance unevenness, reduction in contrast and the like in the liquid crystal display.

The TFT array substrate according to the present invention has a small light leakage current of the TFT of each pixel. For this reason, the TFT array substrate is suitably used in a liquid crystal display having a high front luminance of a backlight. For example, it is also possible to use the TFT array substrate in a liquid crystal display in which a backlight has a front luminance of 3000 cd/m² or more. Consequently, it is possible to implement a liquid crystal display which has a high luminance, is excellent in display characteristics and has few point defects and high quality.

Since the TFT array substrate according to the present invention has a small leakage current, moreover, it is suitably utilized in a liquid crystal display using a lateral electric field method (an IPS method or an FFS method) which has a small storage capacity and shows a sensitive reaction to a leakage current.

A method of manufacturing the TFT array substrate according to the present preferred embodiment will be described below. First of all, a conductive film constituted by a metal such as Al, Cr, Mo, Ti or W serving as a material of the gate wiring 4 or an alloy containing them as main components is formed in a thickness of approximately 100 to 500 nm on the insulating substrate 6 by means of a sputtering device. The conductive film is subjected to patterning through a photomechanical process, an etching step and a resist removing step to form the gate wiring 4.

Next, an insulating film constituted by SiNₓ or the like serving as a material of the insulating film 7 and an amorphous silicon (a-Si) film serving as a material of the semiconductor layer 1 are formed in thicknesses of approximately 150 to 500 nm and approximately 50 to 300 nm on the insulating substrate 6 having the gate wiring 4 formed thereon by means of a plasma CVD device, respectively. In that case, a surface layer portion of the a-Si film is doped with P to form n⁺ type a-Si as an ohmic layer. Then, the semiconductor layer is subjected to the patterning through the photomechanical process, the etching step and the resist removing step to form the semiconductor layer 1. For the semiconductor layer 1, it is also possible to use n-type polycrystalline silicon or an oxide semiconductor, for example, amorphous or polycrystalline In—Ga—Zn-Oxides, or the like in addition to the amorphous silicon (a-Si) film.

Subsequently, a conductive film constituted by a metal such as Al, Cr, Mo, Ti or W serving as materials of the drain electrode 2, the source electrode 3 and the source wiring 5 or an alloy containing them as main components is formed in a thickness of approximately 100 to 500 nm by means of the sputtering device. The conductive film is subjected to the patterning through the photomechanical process, the etching step and the resist removing step to form the drain electrode 2, the source electrode 3 and the source wiring 5. Consequently, the structure of the TFT shown in FIGS. 1 to 3 is obtained.

Thereafter, an SiNₓ film to be an interlayer insulating film is formed in a thickness of approximately 300 nm on the insulating substrate 6 having the TFT formed thereon, and furthermore, a contact hole is formed on the interlayer insulating film through the photomechanical process, the resist removing step and the etching step. Subsequently, a transparent conductive film such as an ITO film is formed in a thickness of approximately 100 nm on the interlayer insulating film including an inner part of the contact hole and is subjected to the patterning through the photomechanical process, the etching step and the resist removing step. Consequently, there is formed a pixel electrode to be connected to the drain electrode 2 of the TFT through the contact hole.

From the foregoing, the TFT array substrate is formed. By using the TFT array substrate, it is possible to manufacture the liquid crystal display according to the present invention.

When creating the TFT array substrate to be utilized in the liquid crystal display using the lateral electric field method, it is also possible to form a pixel electrode by using a metal such as Cr, Al, Mo, Ti or W in place of ITO. Moreover, the pixel electrode may be formed as a part of the drain electrode 2. When creating the TFT array substrate to be utilized in the liquid crystal display using the FFS method, furthermore, it is also possible to form the pixel electrode by using a layer provided directly on or under the drain electrode 2 in contact therewith without providing an interlayer insulating film between the pixel electrode and the drain electrode 2.

### Second Preferred Embodiment

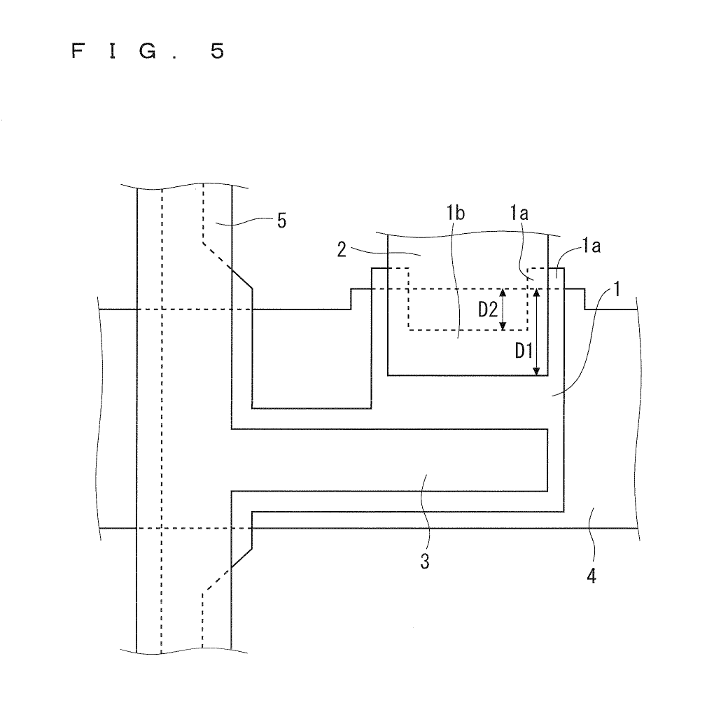

FIG. 4 is a plan view showing a structure of a TFT provided in a TFT array substrate according to a second preferred embodiment. In FIG. 4, the same elements as those shown in FIG. 1 have the same reference numerals. For this reason, their detailed description will be omitted.

Also in the TFT according to the second preferred embodiment, an end face of a semiconductor layer 1 does not intersect with an end face of a source wiring 5, an end face of a source electrode 3 and an end face of a drain electrode 2 over a gate wiring 4 in the same manner as in the first preferred embodiment. Moreover, a portion of the semiconductor layer 1 which is positioned under the drain electrode 2 has a structure including a protruded portion 1a (a first portion) which is protruded outward from the gate wiring 4 as seen in a planar view and has an end face intersecting with the end face of the drain electrode 2, and a retracted portion 1b (a second portion) having an end face retracted from the end face of the gate wiring 4 as seen in a planar view. The protruded portion 1a has a small area in order to suppress a light leakage current. Accordingly, it is possible to obtain the same effect as that in the first preferred embodiment.

In the second preferred embodiment, furthermore, a distance between the end face of the gate wiring 4 in a portion of the semiconductor layer 1 which is protruded from the gate wiring 4 and a surface of the drain electrode 2 which is opposed to the source electrode 3 is maintained to be equal to or greater than 5 μm. In other words, a distance D1 between the protruded portion 1a and the surface of the drain electrode 2 which is opposed to the source electrode 3 is set to be equal to or greater than 5 μm.

By increasing a distance between the protruded portion 1a of the semiconductor layer 1 on which backlight light is irradiated to generate a carrier and a channel region of the semiconductor layer 1 (a portion between the drain electrode 2 and the source electrode 3) as in the present preferred embodiment, it is possible to reduce the number of the carriers to be induced into the channel region more greatly. Consequently, it is possible to further suppress the light leakage current.

It is preferable that a method of manufacturing the TFT array substrate according to the present preferred embodiment should be the same as that in the first preferred embodiment. In the example of FIG. 4, moreover, a convex portion is provided in the vicinity of the protruded portion 1a in the gate wiring 4 in order to increase the distance D1, and a width of the gate wiring 4 in that part is locally increased. If the distance D1 of 5 μm or more can be ensured, however, the gate wiring 4 may take an optional shape.

### Third Preferred Embodiment

FIG. 5 is a plan view showing a structure of a TFT provided in a TFT array substrate according to a third preferred embodiment. Also in FIG. 5, the same elements as those shown in FIG. 1 have the same reference numerals. For this reason, their detailed description will be omitted.

Also in the TFT according to the third preferred embodiment, an end face of a semiconductor layer 1 does not intersect with an end face of a source wiring 5, an end face of a source electrode 3 and an end face of a drain electrode 2 over a gate wiring 4 in the same manner as in the first preferred embodiment. Moreover, a portion of the semiconductor layer 1 which is positioned under the drain electrode 2 has a structure including a protruded portion 1a (a first portion) which is protruded outward from the gate wiring 4 as seen in a planar view and has an end face intersecting with the end face of the drain electrode 2, and a retracted portion 1b (a second portion) having an end face retracted from the end face of the gate wiring 4 as seen in a planar view. The protruded portion 1a has a small area in order to suppress a light leakage current. Accordingly, it is possible to obtain the same effect as that in the first preferred embodiment.

In the third preferred embodiment, furthermore, the end face of the semiconductor layer 1 to be included in the gate wiring 4 under the drain electrode 2 is positioned inward from the end face of the gate wiring 4 by 1.5 μm or more. In other words, a distance D2 at which an end face of the retracted portion 1b of the semiconductor layer 1 is retracted from the end face of the gate wiring 4 is set to be equal to or greater than 1.5 μm.

Backlight light has a component in a diagonal direction in addition to a component in a vertical direction with respect to a display surface of a liquid crystal display. Accordingly, there is a possibility that the component in the diagonal direction of the backlight light might also be irradiated on the retracted portion 1b of the semiconductor layer 1 which is retracted from the end face of the gate wiring 4. However, the component in the diagonal direction of the backlight light becomes weaker when an angle in the vertical direction is increased. When the end face of the retracted portion 1b is retracted from the end face of the gate wiring 4 more greatly, therefore, a strength of the component in the diagonal direction of the backlight light reaching the semiconductor layer 1 is more reduced.

Moreover, there is backlight light (multiple reflected light) which is not blocked by the gate wiring 4 but is subjected to multiple reflection by the drain electrode 2 and the gate wiring 4 and reaches the retracted portion 1b of the semiconductor layer 1. The multiple reflected light is reduced in proportion to a degree of scattering and a light path length over a reflection surface. When the end face of the retracted portion 1b is retracted from the end face of the gate wiring 4 more greatly, therefore, the multiple reflected light reaching the semiconductor layer 1 also becomes weaker.

By retracting the end face of the retracted portion 1b of the semiconductor layer 1 from the end face of the gate wiring 4 by 1.5 μm or more, accordingly, it is possible to decrease the backlight light reaching the semiconductor layer 1, thereby suppressing the generation of a light leakage current still more.

A method of manufacturing the TFT array substrate according to the present preferred embodiment may be the same as that in the first preferred embodiment. In the example of FIG. 5, moreover, a convex portion is provided in a portion of the gate wiring 4 with which the drain electrode 2 overlaps in order to increase the distance D2, and a width of the gate wiring 4 is locally increased in that portion. If the distance D2 of 1.5 μm or more can be ensured, however, the gate wiring 4 may take an optional shape.

Furthermore, it is also possible to employ a structure in which the second preferred embodiment is combined with the third preferred embodiment so that the distance D2 at which the end face of the retracted portion 1b of the semiconductor layer 1 is retracted from the end face of the gate wiring 4 is equal to or greater than 1.5 μm and the distance D1 between the protruded portion 1a and the surface of the drain electrode 2 which is opposed to the source electrode 3 is equal to or greater than 5 μm. Consequently, the light leakage current can further be reduced.

According to the present invention, the respective preferred embodiments can freely be combined or can properly be changed and omitted within the scope of the present invention.

While the invention has been shown and described in detail, the foregoing description is in all aspects illustrative and not restrictive. It is therefore understood that numerous modifications and variations can be devised without departing from the scope of the invention.

What is claimed is:

1. A thin film transistor array substrate comprising:
a gate wiring for driving a pixel electrode constituting a pixel on an insulating substrate;
a source wiring intersecting with said gate wiring through an insulating film;
a source electrode connected to said source wiring;
a drain electrode provided opposite to said source electrode and connected to said pixel electrode; and
a semiconductor layer connected to said source electrode and said drain electrode and provided under said source electrode and said drain electrode,
wherein an end face of said semiconductor layer does not intersect with an end face of said source wiring, an end face of said source electrode and an end face of said drain electrode over said gate wiring, and
a portion of said semiconductor layer which is positioned under said drain electrode has an end face to be included in said gate wiring as seen in a planar view.

2. The thin film transistor array substrate according to claim 1, wherein said portion of said semiconductor layer which is positioned under said drain electrode includes:
a first portion protruded outward from said gate wiring as seen in a planar view and having an end face intersecting with said end face of said drain electrode; and
a second portion having an end face retracted from an end face of said gate wiring as seen in a planar view.

3. The thin film transistor array substrate according to claim 2, wherein a distance from said first portion to a surface of said drain electrode which is opposed to said source electrode is equal to or greater than 5 μm.

4. The thin film transistor array substrate according to claim 2, wherein said end face of said second portion is retracted from said end face of said gate wiring by 1.5 μm or more.

5. A liquid crystal display using the thin film transistor array substrate according to claim 1.

6. The liquid crystal display according to claim 5 which uses a lateral electric field method.

7. The liquid crystal display according to claim 5 comprising a backlight having a front luminance of 3000 cd/m² or more.
